(19) United States
(12) Patent Application Publication
(10) Pub. No.: US 2008/0211065 A1
(43) Pub. Date: Sep. 4, 2008

(54) Semiconductor devices and methods of manufacture thereof

(76) Inventor: Shrinivas Govindarajan, Glen Allen, VA (US)

Correspondence Address: SLATER & MATSIL LLP, 17950 PRESTON ROAD, SUITE 1000, DALLAS, TX, 75252, US

(21) Appl. No.: 11/713,454

(22) Filed: Mar. 2, 2007

(51) Int. Cl. H01L 21/31; H01L 23/58; H01L 21/469

(52) U.S. Cl. 257/635; 438/763; 257/E23.001; 257/E21.24; 438/785

(57) ABSTRACT

Semiconductor devices and methods of manufacture thereof are disclosed. In one embodiment, a method of fabricating a material layer of a semiconductor device includes providing a workpiece, and forming a ZrO₂ layer over the workpiece. The method includes forming at least one monoclinic crystalline phase-minimizing material layer for the ZrO₂ layer over the workpiece.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip.

Insulating materials comprise dielectric materials that are used in many types of semiconductor devices. Silicon dioxide (SiO₂) is a common dielectric material used in semiconductor device manufacturing, for example, which has a dielectric constant or k value of about 3.9. Some semiconductor applications require the use of a high k dielectric material having a higher k value than the k value of silicon dioxide, for example. Some transistors require a high k dielectric material as a gate dielectric material, and some capacitors require a high k dielectric material as an insulating material between two conductive plates, as examples, to reduce leakage current and increase capacitance.

A dynamic random access memory (DRAM) is a memory device that can be used to store information. A DRAM cell in a memory array typically includes two elements: a storage capacitor and an access transistor. Data can be stored into and read out of the storage capacitor by passing a charge through the access transistor and into the capacitor. The capacitance, or the amount of charge held by the capacitor per applied voltage, is measured in farads and depends upon the area of the plates, the distance between them, and the dielectric value of the insulator, as examples.

High k dielectric materials are typically used as an insulating material in the storage capacitor of DRAM cells. Examples of some high dielectric constant materials that have been proposed as capacitor dielectric materials are hafnium oxide and hafnium silicate. Another high dielectric constant material proposed for use in semiconductors is zirconium oxide (ZrO₂). However, when deposited, ZrO₂ may form in several crystalline phases. ZrO₂ as-deposited forms in a monoclinic crystalline phase at ordinary temperatures and low pressures. The monoclinic crystalline phase of ZrO₂ has a lower dielectric constant than other crystalline phases of ZrO₂.

What are needed in the art are improved methods of forming high dielectric constant materials comprising ZrO₂ and structures thereof in semiconductor devices.

### SUMMARY OF THE INVENTION

These and other problems are generally solved or circumvented, and technical advantages are generally achieved, by preferred embodiments of the present invention, which provide improved methods of forming high k dielectric materials comprised of ZrO₂ and structures thereof.

In accordance with a preferred embodiment of the present invention, a method of fabricating a material layer of a semiconductor device includes providing a workpiece, and forming a ZrO₂ layer over the workpiece. The method includes forming at least one monoclinic crystalline phase-minimizing material layer for the ZrO₂ layer over the workpiece.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a semiconductor device in accordance with a preferred embodiment of the present invention, wherein an interface layer is formed over a workpiece;

FIGS. 2 and 3 show a more detailed view of the interface material of FIG. 1 in accordance with embodiments of the present invention;

FIG. 4 shows a cross-sectional view of a semiconductor device in accordance with preferred embodiments of the present invention, wherein a ZrO₂-containing layer is formed over the interface layer;

FIGS. 5 through 9 show more detailed views of the ZrO₂-containing layer of FIG. 4 in accordance with several embodiments of the present invention;

FIG. 10 shows the semiconductor device of FIG. 4 after an electrode material has been formed over the ZrO₂-containing layer;

FIG. 11 shows a cross-sectional view of a semiconductor device, wherein the novel methods of embodiments of the present invention are implemented in a transistor structure;

FIG. 12 shows a cross-sectional view of a semiconductor device, wherein the novel methods of embodiments of the present invention are implemented in a metal-insulator-metal (MIM) capacitor structure; and

FIGS. 13 and 14 show cross-sectional views of a semiconductor device at various stages of manufacturing, wherein the novel methods of embodiments of the present invention are implemented in a DRAM structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The development of high k dielectric materials has conventionally focused on the development of amorphous high k material layers, the conventional belief being that amorphous materials avoid grain boundaries which are potential diffusivity pathways for high leakage current.

Embodiments of the present invention achieve technical advantages by providing novel methods of forming high k dielectric materials and structures thereof, wherein a stabile tetragonal crystalline phase of ZrO₂ is achieved. A layer of ZrO₂ is achieved that has a predominantly tetragonal crystalline phase, also resulting in a dielectric material layer having a low leakage current and a high dielectric constant.

The present invention will be described with respect to preferred embodiments in specific contexts, namely the formation of high k dielectric materials in semiconductor devices such as capacitors and transistors. The invention may also be applied, however, to the formation of dielectric materials in other applications where high k dielectric materials are required, for example.

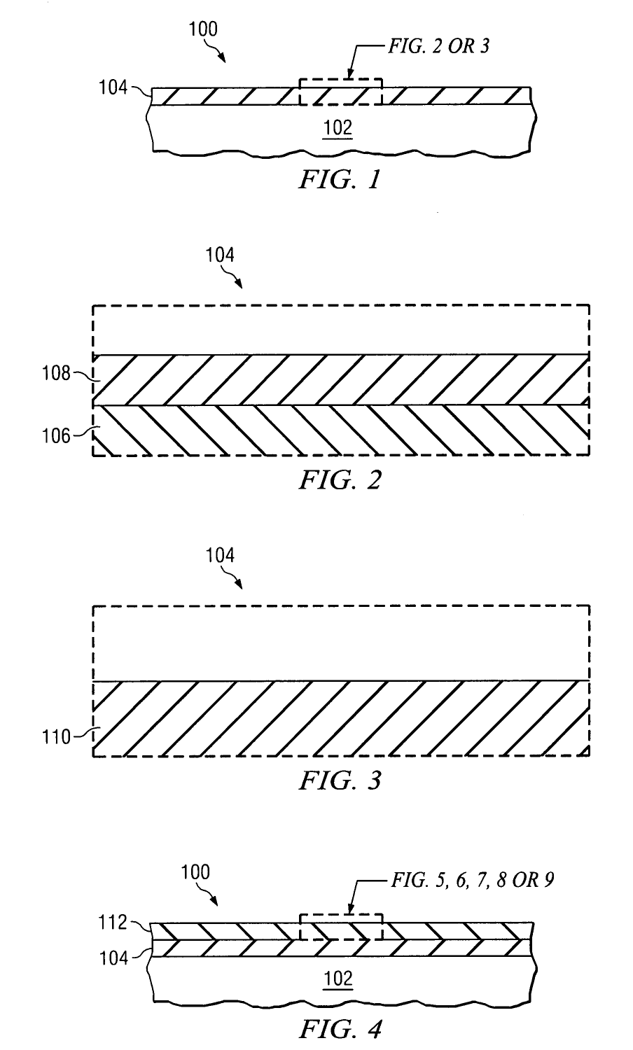

FIG. 1 shows a cross-sectional view of a semiconductor device 100 in accordance with a preferred embodiment of the present invention. The semiconductor device 100 is preferably fabricated by providing a workpiece 102, as shown. The workpiece 102 may include a semiconductor substrate comprising silicon or other semiconductor materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, or SiC, as examples, may be used in place of silicon. The workpiece 102 may comprise a silicon-on-insulator (SOI) substrate, for example.

The workpiece 102 is preferably cleaned, for example, to remove debris, native oxide, and/or contaminants. In a preferred embodiment, the workpiece 102 is cleaned using a hydrogen fluoride (HF) “last” or final cleaning step, for example. Alternatively, other chemicals and processes may be used to clean the workpiece 102, for example.

Next, an optional interface layer 104 may be formed over a workpiece, as shown in FIG. 1. In some embodiments, the interface layer 104 preferably comprises a nitride interface layer 106 formed over the workpiece 102, and a high band gap material layer 108 disposed over the nitride interface layer 106, as shown in FIG. 2 in a more detailed view. In other embodiments, the interface layer 104 preferably comprises a rare earth-containing material layer 110 formed over the workpiece 102, as shown in FIG. 3 in a more detailed view. The interface layer 104 is also referred to herein as a monoclinic crystalline phase-minimizing material layer for a ZrO₂ layer, to be described further herein.

Referring next to FIG. 2, the optional interface layer 104 in some embodiments preferably comprises a nitride interface layer 106 formed over, adjacent to, and abutting the workpiece 102. The nitride interface layer 106 may comprise silicon oxynitride (SiOₓN_{y}), although alternatively, the interface layer 106 may comprise other insulating materials that include nitrogen, for example. In a preferred embodiment, the nitride interface layer 106 is preferably formed by growing an oxide, e.g., about 10 Angstroms of silicon dioxide, using a well-controlled growth process, followed by nitriding the well-controlled oxide by exposing the oxide to a rapid thermal anneal (RTA) process in an ambient of NH₃ at a pressure of around 15 to 45 Torr for greater than about 10 seconds, at a temperature of greater than about 600° C., as examples. This anneal process is also referred to herein as a pre-anneal process, for example. Alternatively, other processing parameters may also be used to form the nitride interface layer 106.

The nitride interface layer 106 preferably comprises a thickness of about 10 Angstroms or less, for example, although alternatively, the nitride interface layer 106 may comprise other dimensions. The nitride interface layer 106 preferably comprises an oxynitride material in some embodiments, for example. The nitride interface layer 106 advantageously provides a good starting surface for the formation of the subsequently-deposited high band gap material layer 108.

A high band gap material layer 108 is disposed or formed over the nitride interface layer 106, also shown in FIG. 2. The high band gap material layer 108 is also referred to herein as a high band gap material, for example. The high band gap material layer 108 preferably comprises about 3 to 15 Angstroms of Al₂O₃, in some embodiments. The high band gap material layer 108 may also comprise about 15 Angstroms or less of Al₂O₃, SiO₂, Si₃N₄, combinations thereof, or multiple layers thereof, as examples, although alternatively, the high band gap material layer 108 may comprise other dimensions and materials.

If the high band gap material 108 comprises Al₂O₃, the high band gap material 108 may be formed using atomic layer deposition (ALD), e.g., using tri-methyl aluminum (TMA) as a precursor for Al and ozone (O₃) or H₂O as an oxidant, at a temperature of about 400 to 450° C., as an example, although other methods may also be used to form the Al₂O₃. The high band gap material layer 108 may be formed using ALD, chemical vapor deposition (MOCVD), physical vapor deposition (PVD), or other deposition methods, for example.

The high band gap material 108 preferably comprises a material having an offset of greater than about 1.5 eV to the conduction band of silicon, for example. The high band gap material layer 108 preferably comprises a material adapted to minimize the formation of a monoclinic crystalline phase of a subsequently deposited ZrO₂-containing material layer (not shown in FIG. 2; see ZrO₂-containing material layer 112 in FIG. 4) in some embodiments, for example, to be described further herein. The nitride interface layer 106 and the high band gap material 108 form the interface layer 104 in this embodiment.

Alternatively, the interface layer 104 may comprise a single layer of material 10 adapted to minimize the formation of a monoclinic crystalline phase of a subsequently deposited ZrO₂-containing material layer, as shown in FIG. 3. The layer of material 10 preferably comprises an insulating material having the composition REScO₃, wherein RE comprises a rare earth element. The rare earth element RE may comprise La, Gd, Dy, Y, or combinations thereof, as examples, although the rare earth element RE may also comprise other elements. The layer of material 10 preferably comprises a thickness of about 25 Angstroms or less, and the layer of material 10 may be deposited by ALD, CVD, or PVD, as examples, although alternatively, the layer of material 10 may comprise other dimensions and may be deposited using other deposition methods.

Note that optionally, the interface layer 104 may include a nitride interface layer 106 formed adjacent to the workpiece 102, beneath the layer of material 110, in some embodiments, as shown in FIG. 2 (the optional nitride interface layer 106 is not shown in FIG. 3).

Next, a ZrO₂-containing material layer 112 is formed over the optional interface layer 104, as shown in FIG. 4, or the ZrO₂-containing material layer 112 is formed directly over the workpiece 102 if the interface layer 104 is not included. The ZrO₂-containing material layer 112 preferably comprises at least one material layer comprising ZrO₂, for example. The ZrO₂-containing material layer 112 may comprise two or more material layers comprising ZrO₂, as another example. The ZrO₂-containing material layer 112 preferably comprises a thickness of about 200 Angstroms or less, and more preferably comprises a thickness of about 50 to 150 Angstroms, as examples, although alternatively, the ZrO₂-containing material layer 112 may comprise other dimensions. The nitride interface layer 106 and the ZrO₂-containing material layer 112 together may comprise a dielectric material layer having a thickness of about 200 Angstroms or less, in some embodiments, for example. The ZrO₂-containing material layer 112 is also referred to herein as a ZrO₂ layer, at least one ZrO₂ layer, a dielectric layer, or a dielectric material layer, for example.

In some embodiments, forming the ZrO₂-containing material layer 112 preferably comprises forming a dielectric layer 112 using atomic layer deposition (ALD). Forming the dielectric layer 112 may comprise deposition of zirconium dioxide film using tetrakis ethylmethylamido zirconia (TEMAZr) as a precursor in an ALD process and using ozone as an oxidant. The processing conditions for the ZrO₂ layer 112 ALD deposition may comprise ALD cycles with TEMAZr pulses of about 1 to 5 seconds and ozone pulses of about 1 to 5 seconds in duration, with a wafer temperature during the deposition process of about 300+/−40° C., for example. The pulsed TEMAZr and ozone may be alternately introduced until a desired thickness of the dielectric layer 112 is obtained. Alternatively, other processing parameters may also be used to form the ZrO₂ layer 112. Alternatively, other precursors, reactants, and conditions may be used to form the dielectric material 112, for example, and other deposition processes such as CVD or PVD may also be used.

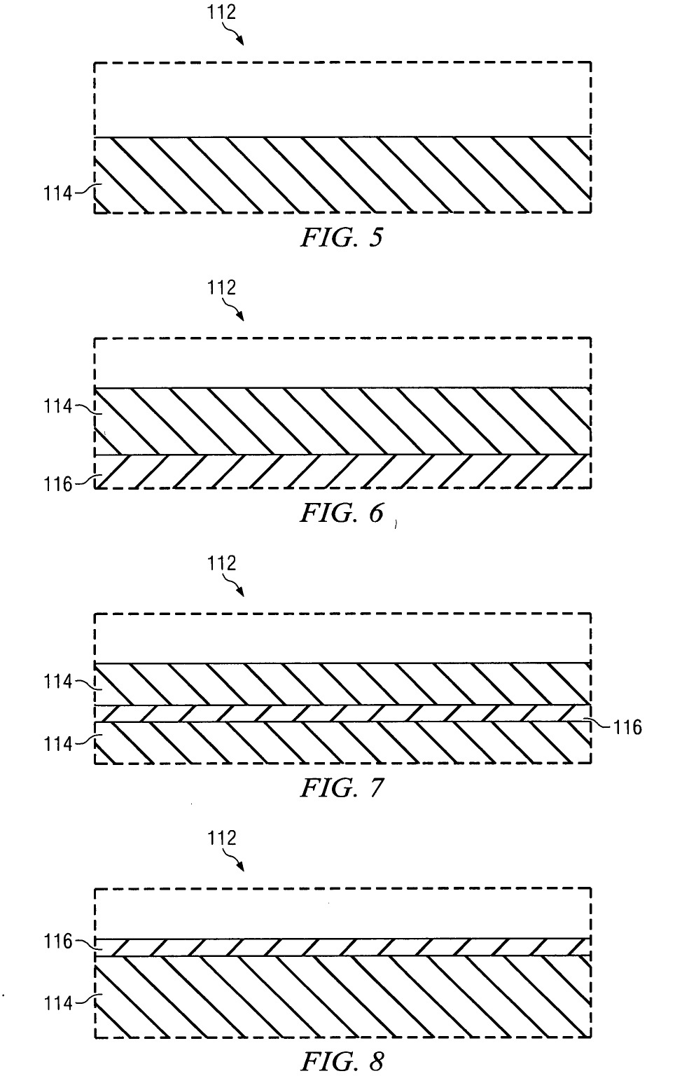

FIGS. 5 through 9 show more detailed views of the ZrO₂-containing layer 112 shown in FIG. 4 in accordance with several embodiments of the present invention. FIG. 5 shows a cross-sectional view of an embodiment of the present invention wherein the ZrO₂-containing layer 112 comprises a layer of pure ZrO₂ 114. The layer of pure ZrO₂ 114 may be formed using CVD, PVD, or several ALD cycles, as examples. The layer of pure ZrO₂ 114 is also referred to herein as a ZrO₂ layer, for example.

In other embodiments, an insulating material layer 116 comprised of a different material than ZrO₂ may be disposed or formed on one or more places: beneath the ZrO₂ layer 114, as shown in FIG. 6; within the ZrO₂ layer 114, as shown in FIG. 7; above the ZrO₂ layer 114, as shown in FIG. 8; or combinations thereof. The insulating material layer 116 preferably comprises a monoclinic crystalline phase-minimizing material layer for the ZrO₂ layer 114. The insulating material layer 116 comprising the monoclinic crystalline phase-minimizing material layer is preferably adapted to cause the ZrO₂ layer 114 to form in a predominantly tetragonal crystalline phase either during the deposition process and/or after a subsequent anneal process, for example.

The insulating material layer 116 preferably comprises a high band gap material 116, for example. The high band gap material 116 preferably comprises a material having an offset of greater than about 1.5 eV to the conduction band of silicon. The high band gap material 116 preferably comprises about 3 to 15 Angstroms of Al₂O₃, in some embodiments. The high band gap material 116 may comprise about 15 Angstroms or less of Al₂O₃, SiO₂, Si₃N₄, combinations thereof, or multiple layers thereof, as examples, although alternatively, the high band gap material 116 may comprise other dimensions and materials. The high band gap material 116 may comprise the same material as, or a different material than, the high band gap material layer 108 of the interface layer 104 shown in FIG. 2, for example. A semiconductor device 100 may include both high band gap material 116 and high band gap material layer 108 in the structure, and may comprise a plurality of layers of high band gap material 116, for example, not shown.

Note that in the embodiment shown in FIG. 6, the optional interface layer 104 may comprise a single layer of a nitride interface layer 106 shown in FIG. 2, for example. In this embodiment, the insulating material layer 116 comprised of a high band gap material 116 is disposed or formed directly beneath the ZrO₂ layer 114 within the ZrO₂-containing layer 112; thus, high band gap material layer 108 may not be required in the structure in the interface layer 104 for minimizing the formation of the monoclinic phase of the ZrO₂ layer 112.

Either the high band gap material layer 108, the high band gap material 116, or both the high band gap material layer 108 and the high band gap material 116 may be included in the semiconductor device 100, for example. In some embodiments, either the high band gap material layer 108 or the high band gap material 116 are included in the semiconductor device 100, but not both, as another example.

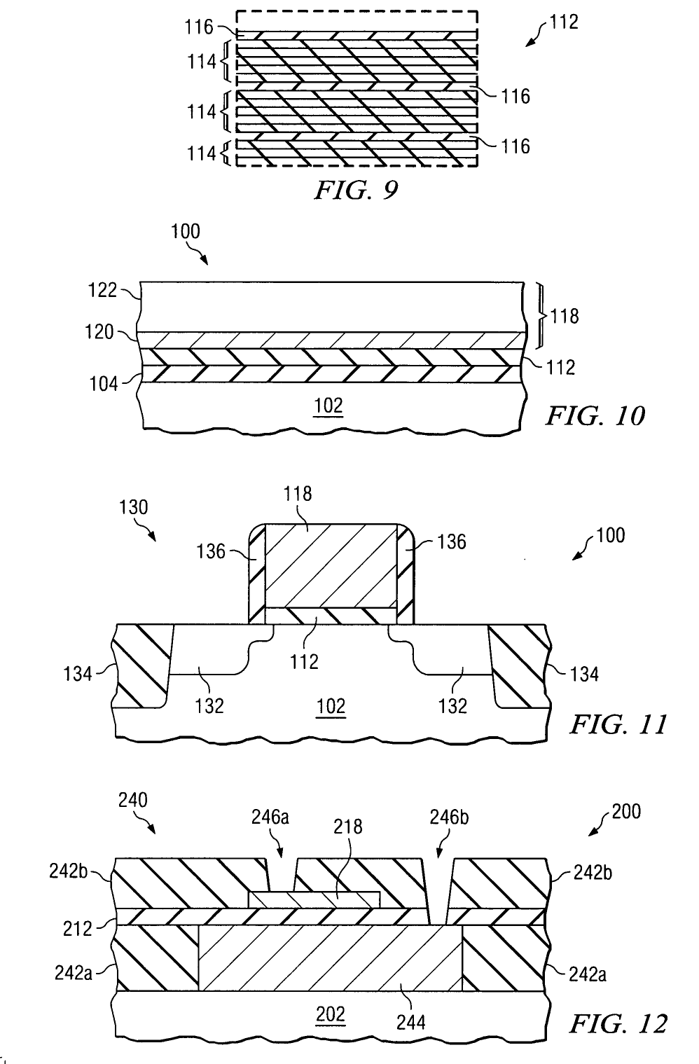

FIG. 9 shows a more detailed view of the ZrO₂-containing layer 112 of FIG. 4 in accordance with yet another embodiment of the present invention, wherein the ZrO₂-containing layer 112 comprises a plurality of layers of ZrO₂ and at least one layer of the high band gap material 116. The ZrO₂-containing layer 112 comprises a plurality of layers of ZrO₂ in this embodiment, for example. The ZrO₂-containing layer 112 may comprise multiple layers of ZrO₂ 114 and multiple layers of the high band gap material 116 such as Al₂O₃. The layers of ZrO₂ 114 and layers of the high band gap material 116a may comprise nanolaminate layers, for example. Alternating layers of ZrO₂ and Al₂O₃ having a variable thickness of a ZrO₂:Al₂O₃ ratio thickness may be formed, for example, by varying the number of ALD cycles for ZrO₂ and Al₂O₃. Other high band gap materials such as SiO₂ or Si₃N₄, or combinations or alternating multiple layers thereof with Al₂O₃, may also be used for the high band gap material 116, for example. Each ALD deposited layer 114 and 116 (although other deposition methods may also be used) may comprise a thickness of about an Angstrom or less, e.g., about 0.7 Angstroms of material may be formed for each ALD cycle. Alternatively, the layers 114 and 116 may comprise smaller or larger dimensions, for example.

After the ZrO₂-containing layer 112 is formed or deposited, the workpiece 102 is preferably subjected to a post-deposition anneal (PDA) process. The PDA process preferably comprises an anneal process in a nitrogen ambient. For example, the workpiece 102 may be annealed in an ambient of NH₃ at a pressure of about 15 to 45 Torr for greater than about 10 seconds at a temperature of greater than about 600° C., although alternatively, other processing parameters may also be used.

The optional pre-anneal process and post-deposition anneal process decrease roughness of the top surface of the material layers disposed on the workpiece 102, and decrease the thickness of the interface layer 104, for example. The post-deposition anneal process also densifies the dielectric material 112, as another example.

FIG. 10 shows the semiconductor device 100 of FIG. 4 after an electrode material 118 has been formed over the ZrO₂-containing layer 112. The electrode material 118 is preferably formed by forming a first material layer 120 over the ZrO₂-containing layer 112, and forming a second material layer 122 over the first material layer 120. The second material layer 122 is different than the first material layer 120; e.g., the second material layer 122 preferably comprises a different material than the material of the first material layer 120.

The first and second material layers 120 and 122 of the electrode material 118 preferably comprise conductive materials. The first material layer 120 is also referred to herein as a first conductive material, and the second material layer 122 is also referred to herein as a second conductive material, for example.

The first material layer 1.20 preferably comprises a metal, in some embodiments, for example. The first material layer 120 of the electrode material 118 preferably comprises a metal with a high thermal stability, such as TiN, TaN, TiCN, TaCN, or multiple layer or combinations thereof, as examples. Alternatively, the first material layer 120 may comprise other materials. The first conductive material 120 preferably comprises a thickness of about 20 nm or less, and more preferably comprises a thickness of about 70 to 150 Angstroms of a material deposited by ALD, metal oxide CVD (MOCVD), PVD, or other deposition methods.

The electrode material 118 preferably includes an optional layer of a second material layer 122 disposed over the first material layer 120, as shown in FIG. 10. The second material layer 122 preferably comprises a layer of semiconductive material 122 comprising about 100 nm of polysilicon, as an example, although alternatively, the layer of semiconductive material 122 may comprise other materials and dimensions. The second material layer 122 may be doped with dopants to increase the conductivity of the semiconductive material, for example.

Next, the workpiece 102 is annealed using an anneal process. The anneal process preferably comprises an activation anneal process comprising a temperature greater than the temperature of the pre-anneal process and PDA process after the dielectric materials 104 and 112 are deposited, for example. The anneal process preferably comprises a temperature of greater than about 1,000° C., for example. The anneal process may comprise an anneal process at about 1,050° C. for about 30 seconds in an N₂ ambient or other nitrogen ambient, as an example. The anneal process may comprise an anneal process for greater than about 10 seconds in an ambient of N₂, wherein the N₂ concentration is greater than about 90%, an another example. The anneal process may comprise a high temperature rapid thermal process in a nitrogen rich ambient for greater than about 5 seconds in other embodiments, for example. Alternatively, other processing parameters may be used for the anneal process, for example. The final anneal process preferably results in a predominantly tetragonal crystallization of the ZrO₂-containing layer 112 in some embodiments, for example.

Embodiments of the present invention include methods of fabricating material layers of semiconductor devices, as described herein. Embodiments of the present invention also include methods of fabricating semiconductor devices. Embodiments of the present invention further include semiconductor devices, transistors, and capacitors manufactured using the novel methods described herein.

For example, the material layers 104, 112, and 118 may then be patterned using lithography to form transistors or capacitors from at least the electrode material 118 and the dielectric layer 104 (not shown in FIG. 10; see FIGS. 11 through 14 which will be described later herein). After the final high temperature anneal process, the various material layers 118, 112, and 104 are then patterned into desired shapes for the semiconductor device 100. For example, the material layers 118 that are conductive may be patterned in the shape of a capacitor plate, a transistor gate, or other conductive elements or portions of circuit elements, as examples. The material layers 112 and 104 comprising the dielectric stack that are insulators may also be patterned, for example.

The novel methods and structures described herein are shown implemented in a planar structure in FIGS. 1 through 10. The novel methods and structures of embodiments of the present invention may also be implemented in non-planar structures, for example.

FIG. 11 shows a cross-sectional view of a semiconductor device 100, wherein the novel processing methods, high k dielectric materials 112 (and also optional interface layer 104, not shown), and electrode material 118 of embodiments of the present invention are implemented in a transistor 130 structure. The high k dielectric material 112 is implemented as a gate dielectric material 112, and the electrode material 118 is implemented as a transistor gate. Optional interface layer 104 may also be included in the structure disposed beneath the high k dielectric material 112, for example, not shown.

The transistor 130 includes a gate dielectric comprising the novel high k dielectric material layer 112 (and optionally, also interface layer 104) described herein and a gate electrode 118 formed over the high k dielectric material layer 112. Source and drain regions 132 are formed proximate the gate electrode 118 in the workpiece 102, and a channel region is disposed between the source and drain regions 132 in the workpiece 102. The transistor 130 may be separated from adjacent devices by shallow trench isolation (STI) regions 134, and insulating spacers 136 may be formed on sidewalls of the gate electrode 118 and the gate dielectric 112, as shown.

FIG. 12 shows a cross-sectional view of a semiconductor device 200 wherein the novel processing methods, high k dielectric material 212, and electrode material 218 of embodiments of the present invention are implemented in a metal-insulator-metal (MIM) capacitor 240 structure, for example. Again, like numerals are used for the various elements that were used to describe the previous figures, and to avoid repetition, each reference number shown in FIG. 12 is not described again in detail herein. Like numerals are used for the various elements that were described in FIGS. 1 through 11. To avoid repetition, each reference number shown in FIG. 12 is not described again in detail herein. Rather, similar materials x04, x06, x08, etc . . . are preferably used for the various material layers shown as were used to describe FIGS. 1 through 11, where x=1 in FIGS. 1 through 11 and x=2 in FIG. 12.

To form the MIM capacitor 240, a bottom capacitor plate 244 is formed over a workpiece 202. The bottom plate 244 may comprise a semiconductive material such as polysilicon, or a conductive material such as TiN, TaN, TiTaN, Ru, RuₓO, TiHfN, TiCN, TaCN, TiXN, AlN, Re₁Re₂N, wherein X comprises a rare earth or transition metal element, wherein RE₁RE₂N comprises a nitride of a first rare earth element RE₁ and a second rare earth element RE₂, and wherein the second rare earth element comprises a different rare earth element than the first rare earth element, as examples, although other materials such as a semiconductor material, e.g., polysilicon may also be used. The bottom capacitor plate 244 may be formed in an insulating material 242a that may comprise an inter-level dielectric layer (ILD), for example. The bottom capacitor plate 244 may include liners and barrier layers, for example, not shown.

The novel high k dielectric material 212 (and also optional interface layer 104, not shown) described with reference to FIGS. 1 through 11 is formed over the bottom plate 244 and the insulating material 242a. An electrode material 218 is formed over the dielectric material 212, as shown in FIG. 12, and the electrode material 218 is patterned to form a top capacitor plate. An additional insulating material 242b may be deposited over the top capacitor plate 218, and the insulating material 242b may be patterned with patterns 246a and 246b for contacts that will make electrical contact to the top plate 218 and the underlying bottom plate 244, respectively. The insulating material 242b may be filled in later with a conductive material to form the contacts in patterns 246a and 246b, for example, not shown.

Thus, in FIG. 12, a capacitor 240 is formed that includes the two conductive plates 244 and 218 separated by an insulator which comprises the novel high k dielectric material 212 (and optional interface layer 104 shown in FIGS. 1 through 3) in accordance with embodiments of the present invention. The capacitor 240 may be formed in a front-end-of the line (FEOL), or portions of the capacitor 240 may be formed in a back-end-of the line (BEOL), for example. One or both of the capacitor plates 244 and 218 may be formed in a metallization layer of the semiconductor device 200, for example. Capacitors 240 such as the one shown in FIG. 12 may be used in filters, in analog-to-digital converters, memory devices, control applications, and many other types of applications, for example.

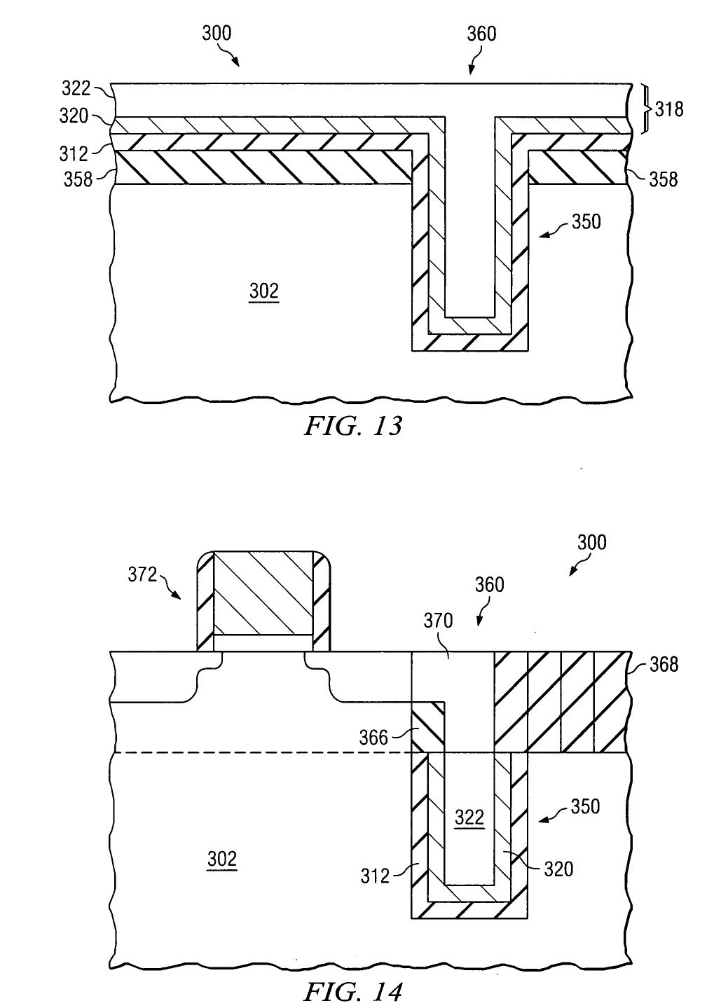

FIGS. 13 and 14 show cross-sectional views of a semiconductor device 300 at various stages of manufacturing, wherein the novel processing methods, high k dielectric material 312 (and optional interface layer 104, not shown) of embodiments of the present invention are implemented in a DRAM 350 structure. To form a DRAM memory cell 350 comprising a storage capacitor utilizing the novel high k dielectric material 312 of embodiments of the present invention, a sacrificial material 358 comprising an insulator such as a hard mask material is deposited over a workpiece 302, and deep trenches 360 are formed in the sacrificial material 358 and the workpiece 302. The novel high k dielectric material layer 312 and optional nitride layer 104 (not shown) are formed over the patterned sacrificial material 358 and the workpiece 302, and an electrode material 318 is formed over the high k dielectric material layer 312, as shown. The electrode material 318 may comprise a first material layer 320 comprising a metal, and a second material layer 322 comprised of polysilicon that may be doped with n or p-type doping, for example.

Next, excess amounts of electrode materials 320 and 322 and dielectric material 312 are removed from over the top surface of the workpiece 302, e.g., using a chemical mechanical polish (CMP) process and/or etch process. The materials 320 and 322, and high k dielectric material layer 312 are also recessed below the top surface of the workpiece 302, for example. The sacrificial material 358 is also removed, as shown in FIG. 14.

An oxide collar 366 may be formed by thermal oxidation of exposed portions of the trench 360 sidewalls. The trench 360 may then be filled with a conductor such as polysilicon 370. Both the polysilicon 370 and the oxide collar 366 are then etched back to expose a sidewall portion of the workpiece 302 which will form an interface between an access transistor 372 and the capacitor formed in the deep trench 360 in the workpiece 302, for example.

After the collar 366 is etched back, a buried strap may be formed at 370 by deposition of a conductive material, such as doped polysilicon. Regions 370 comprising polysilicon are preferably doped with a dopant such as arsenic or phosphorus, for example. Alternatively, regions 370 may comprise a conductive material other than polysilicon (e.g., a metal).

The strap material 370 and the workpiece 302 may then be patterned and etched to form STI regions 368. The STI regions 368 may be filled with an insulator such as an oxide deposited by a high density plasma process (i.e., HDP oxide). The access transistor 372 may then be formed to create the structure shown in FIG. 14.

The workpiece 302 proximate the high k dielectric material layer 312 lining the deep trench 360 comprises a first capacitor plate, the high k dielectric material layer 312 (and optional interface layer 104, not shown) comprises a capacitor dielectric, and materials 320 and 322 comprise a second capacitor plate of the deep trench storage capacitor of the DRAM memory cell 350. The access transistor 372 is used to read or write to the DRAM memory cell 350, e.g., by the electrical connection established by the strap 370 to a source or drain of the transistor 372 near the top of the deep trench 360, for example.

Embodiments of the present invention may also be implemented in other structures that require a dielectric material. For example, the novel processing methods and high k dielectric material layers 104/112, 212, and 312 described herein may be implemented in planar transistors, vertical transistors, planar capacitors, stacked capacitors, vertical capacitors, deep or shallow trench capacitors, and other devices. Embodiments of the present invention may be implemented in stacked capacitors where both plates reside above a substrate or workpiece 102, 202, and 302, for example.

Experimental test results of embodiments of the present invention show that EOT increase is minimal, and that the formation of a monoclinic phase of ZrO₂ is minimized, using the methods and structures described herein.

Advantages of embodiments of the present invention include providing novel methods and structures having a high dielectric constant or k value. The structures formed are thermally stable and result in capacitors having a low effective oxide thickness (EOT) and low leakage current, for example. The final high temperature anneal process advantageously stabilizes the high k phase, e.g., a tetragonal crystalline phase, of the ZrO₂ material layers in the dielectric layer 112, 212, and 312, for example. The ZrO₂ material layers of the dielectric layer 112, 212, and 312 may comprise a low k crystalline phase as-deposited, and the high temperature anneal process later converts the ZrO₂ of the dielectric material 112, 212, and 312 to a predominantly high k tetragonal crystalline phase, for example. The tetragonal phase of the ZrO₂ is advantageously stabilized, retained, and/or maintained after the anneal process.

Embodiments of the present invention achieve technical advantages by providing novel processing solutions for the formation of a high k phase dielectric material comprised of ZrO₂. The novel dielectric materials 104/112, 212, and 312 described herein have high k values, low leakage currents, good uniformity, and high temperature thermal stability. The novel electrode materials and methods of forming thereof have increased diffusion barrier properties, have decreased leakage, and minimally impact the effective oxide thickness (EOT) of the dielectric material layers disposed beneath the electrode materials.

The entire dielectric stack of the high k materials 104/112, 212, and 312 described herein, advantageously may have a dielectric constant of about 25 or greater in some embodiments, and more preferably has a dielectric constant of greater than 30 in other embodiments, for example.

Embodiments of the invention provide processing pathways for minimizing EOT and also minimizing the formation of a monoclinic phase for zirconium dioxide dielectrics. The methods described herein minimize as-deposited EOT and also minimize a subsequent EOT increase with post anneal thermal cycling.

Benefits of forming the optional nitrided starting surface (e.g., nitride interface layer 106 of interface layer 104 shown in FIG. 2) include eliminating the formation of a lower dielectric constant zirconium dioxide phase, providing a nitrided starting “template” to enhance the formation of tetragonal zirconium dioxide phase, and also, minimizing EOT increase with post deposition annealing by providing a barrier for oxygen diffusion to the silicon interface.

The at least one ZrO₂ layer 112 advantageously comprises a material layer comprising about 80% or greater of a tetragonal crystalline phase of ZrO₂. The remaining 20% of the material of the ZrO₂ layer(s) 112 may comprise other types of crystalline forms of ZrO₂ (e.g., monoclinic, orthorhombic I, orthorhombic II, or cubic) or may be amorphous, for example. More preferably, about 90% of the ZrO₂ layer 112 comprises a tetragonal crystalline phase, further increasing the dielectric constant of the dielectric material 104 and 112.

The insertion of a high band gap material 108 and/or 116, e.g., comprising Al₂O₃ or other high band gap materials as described herein, advantageously reduces leakage of the dielectric material 104/112, 212, and 312 due to tunneling and also promotes a high k tetragonal crystalline phase formation in the ZrO₂ of the dielectric material 104/112, 212, and 312, for example. The insertion of a high band gap material 108 and/or 116 in the dielectric material stack 104/112, 212, and 312 interrupts the formation of the low k monoclinic phase of the ZrO₂.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method of fabricating a material layer of a semiconductor device, the method comprising:
providing a workpiece;
forming a ZrO₂ layer over the workpiece; and
forming at least one monoclinic crystalline phase-minimizing material layer for the ZrO₂ layer over the workpiece.

2. The method according to claim 1, wherein forming the ZrO₂ layer comprises forming a dielectric material layer comprising a predominantly tetragonal crystalline phase of ZrO₂.

3. The method according to claim 1, wherein forming the at least one monoclinic crystalline phase-minimizing material layer for the ZrO₂ layer comprises forming an insulating material layer comprised of a different material than ZrO₂ beneath the ZrO₂ layer, within the ZrO₂ layer, above the ZrO₂ layer, or combinations thereof.

4. The method according to claim 3, wherein forming the insulating material layer comprises forming a high band gap material, the high band gap material having an offset of greater than about 1.5 eV to a conduction band of silicon.

5. The method according to claim 4, wherein forming the high band gap material comprises forming about 15 Angstroms or less of Al₂O₃, SiO₂, Si₃N₄, combinations thereof, or multiple layers thereof.

6. The method according to claim 1, wherein forming the ZrO₂ layer comprises forming a plurality of layers of ZrO₂.

7. A method of fabricating a semiconductor device, the method comprising:
providing a workpiece;
forming a dielectric layer over the workpiece, the dielectric layer comprising at least one ZrO₂ layer and at least one monoclinic crystalline phase-minimizing material layer for the ZrO₂ layer; and
annealing the workpiece.

8. The method according to claim 7, wherein forming the dielectric layer over the workpiece comprises, first, forming the at least one monoclinic crystalline phase-minimizing material layer for the ZrO₂ layer over the workpiece, the at least one monoclinic crystalline phase-minimizing material layer for the ZrO₂ layer comprising an interface layer disposed over and adjacent to the workpiece, and second, forming the at least one ZrO₂ layer over and adjacent to the interface layer.

9. The method according to claim 8, wherein forming the interface layer comprises forming a layer of SiOₓN_{y} comprising a thickness of about 10 Angstroms or less.

10. The method according to claim 9, wherein forming the interface layer further comprises forming a layer of about 15 Angstroms or less of Al₂O₃, SiO₂, Si₃N₄, combinations thereof, or multiple layers thereof, over the layer of SiOₓN_{y}.

11. The method according to claim 8, wherein forming the at least one monoclinic crystalline phase-minimizing material layer for the ZrO₂ layer over the workpiece comprises forming an interface layer comprising a composition REScO₃, wherein RE comprises a rare earth element.

12. The method according to claim 11, wherein forming the interface layer comprises forming an interface layer comprising REScO₃ wherein the rare earth element comprises La, Gd, Dy, Y, or combinations thereof.

13. A method of fabricating a semiconductor device, the method comprising:
providing a workpiece;
forming a dielectric material over the workpiece, the dielectric material comprising ZrO₂ having a predominantly tetragonal crystalline phase, the dielectric material further comprising at least one layer of a material adapted to minimize a formation of a mono clinic crystalline phase of the ZrO₂ layer;
forming an electrode material over the dielectric material; and
annealing the workpiece.

14. The method according to claim 13, wherein forming the electrode material comprises forming a first material layer and forming a second material layer over the first material layer, wherein the second material layer is different than the first material layer.

15. The method according to claim 13, wherein forming the first material layer comprises forming a metal, and wherein forming the second material layer comprises forming a semiconductive material.

16. The method according to claim 13, further comprising forming a transistor or capacitor from the dielectric material and the electrode material.

17. The method according to claim 13, wherein annealing the workpiece comprises annealing the workpiece at a temperature of greater than about 1,000° C.

18. A semiconductor device manufactured according to the method of claim 13.

19. A semiconductor device, comprising:
a workpiece;
an interface layer disposed over the workpiece, the interface layer comprising SiOₓN_{y} or REScO₃, wherein RE comprises a rare earth element; and
at least one ZrO₂ layer disposed over the interface layer, the at least one ZrO₂ layer comprising a predominantly tetragonal crystalline phase.

20. The semiconductor device according to claim 19 wherein the at least one ZrO₂ layer comprises a material layer comprising about 80% or greater of a tetragonal crystalline phase.

21. The semiconductor device according to claim 19, wherein the interface layer and the at least one ZrO₂ layer comprise a dielectric material layer having a dielectric constant of about 25 or greater.

22. The semiconductor device according to claim 19, wherein the interface layer and the at least one ZrO₂ layer comprise a dielectric material layer having a thickness of about 200 Angstroms or less.

23. The semiconductor device according to claim 19, wherein the at least one ZrO₂ layer comprises a plurality of layers of ZrO₂.

24. The semiconductor device according to claim 19, further comprising at least one layer of an insulating material different than ZrO₂ disposed beneath the ZrO₂ layer, within the ZrO₂ layer, above the ZrO₂ layer, or combinations thereof.

25. The semiconductor device according to claim 24, wherein the at least one layer of the insulating material comprises Al₂O₃, SiO₂, Si₃N₄, or combinations or multiple layers thereof
